(19) United States
(12) Patent Application Publication
(10) Pub. No.: US 2024/0086725 A1
(43) Pub. Date: Mar. 14, 2024

(54) TIME SERIES MODELING PREDICTIONS USING PARTIAL HISTORY

(71) Applicant: DataRobot, Inc., Boston, MA (US)

(72) Inventors: Jonas Marius Vilkas, Lexington, MA (US); Mykhailo Poliakov, Kyiv (UA); Iryna Kovalchuk, Lviv (UA)

(73) Assignee: DataRobot, Inc., Boston, MA (US)

(21) Appl. No.: 18/241,166

(22) Filed: Aug. 31, 2023

Related U.S. Application Data
(60) Provisional application No. 63/405,643, filed on Sep. 12, 2022.

(51) Int. Cl. G06N 5/02; G06F 11/34

(52) U.S. Cl. CPC G06N 5/02; G06F 11/3409

(57) ABSTRACT

Aspects of this technical solution can segment a first time period for the first series into a second time period bounded by a first time stamp and a second time stamp later than the first time stamp, and into a third time period bounded by a third time stamp later than the second timestamp and a fourth time stamp later than the third time stamp, determine a metric for the third time period and based on first data points of a training data set for the first series and having time stamps bounded by the first time stamp and the second time stamp within the second time period, generate data points within the third time period based on the first metric and generate data points corresponding to a performance of a second series subsequent to the prediction time stamp.

### CROSS-REFERENCE TO RELATED PATENT APPLICATIONS

This application claims the benefit of priority under 35 U.S.C. § 119 to U.S. Provisional Patent Application Ser. No. 63/405,643, entitled “TIME SERIES MODELING PREDICTIONS USING PARTIAL HISTORY,” filed Sep. 12, 2022, the contents of all such applications being hereby incorporated by reference in its their entirety and for all purposes as if completely and fully set forth herein.

### TECHNICAL FIELD

The disclosures relates generally to machine learning systems, and more particularly to generating models of predicted performance of series having partial history or no history.

### INTRODUCTION

Understanding future behavior of complex systems is increasingly important to effective modeling of multivariate simulation systems, for example. Understanding future behavior of systems at higher level is granularity is thus desired. However, it can be challenging to efficiently and effectively obtain sufficient data to generate behavior for future behavior over time. Thus, an ability to provide and enable insight into behavior of systems over time is desired.

### SUMMARY

Aspects of this technical solution are directed to generating machine learning models with predictive capability with limited to no historical data. Present implementations can segment timestamped data to infer potential performances of a series based on the partial presence or absence of data in the data set for a series. A system can detect an absence of data points where no data point exist in a particular time range, and can detect a partial presence of data points where data points exist for some, but not all, data points in a series, time stamps corresponding to a series, or time steps corresponding to a particular granularity associated with a series or machine learning model. The time steps can be various multiples of a minimum time step or minimum distance between timestamps. Segmentation of a series can achieve a technical improvement of creating accurate metrics each corresponding to particular portions of a series. A model can identify metrics corresponding to particular segments of particular series. Based on the metrics, the model can generate a performance for a series having no or partial history and including data points having time stamps later than any time stamps associated with the input series or segments. This this technical solution can provide a technical improvement of generating a predictive performance for a series from a “cold-start” state corresponding to a lack of historical data for that series on which to base a model of predictive performance. Thus, a technological solution for generating models of predicted performance of series having partial history or no history is provided.

Aspects of this technical solution are directed to a system. The system can include a data processing system with memory and one or more processors. The data processing system can receive, via a user interface, an indication of a first series associated with one or more time stamps before a prediction time stamp indicating a start time of a prediction range. The data processing system can segment a first time period associated with the first series into a second time period bounded by a first time stamp within the first time period and a second time stamp within the first time period and later than the first time stamp, and into a third time period bounded by a third time stamp within the first time period and later than the second timestamp and a fourth time stamp within the first time period and later than the third time stamp. The data processing system can determine a first metric associated with the third time period and based on one or more first data points of a training data set associated with the first series and having time stamps bounded by the first time stamp and the second time stamp within the second time period. The data processing system can generate one or more data points within the third time period based on the first metric. The data processing system can generate, based on a model using machine learning and input can include the data points generated within the third time period, one or more data points corresponding to a performance of a second series subsequent to the prediction time stamp. The data processing system can present, via the user interface, a first presentation that indicates the performance of the second series subsequent to the prediction time stamp in a coordinate space including the third time period. The data processing system can present, via the user interface, a second presentation that indicates a region in the coordinate space including the third time period, the region corresponding to the performance of the second series subsequent to the prediction time stamp.

Aspects of this technical solution are directed to a method. The method can include receiving, via a user interface, an indication of a first series associated with one or more time stamps before a prediction time stamp indicating a start time of a prediction range. The method can include segmenting a first time period associated with the first series into a second time period bounded by a first time stamp within the first time period and a second time stamp within the first time period and later than the first time stamp, and into a third time period bounded by a third time stamp within the first time period and later than the second timestamp and a fourth time stamp within the first time period and later than the third time stamp. The method can include determining a first metric associated with the third time period and based on one or more first data points of a training data set associated with the first series and having time stamps bounded by the first time stamp and the second time stamp within the second time period. The method can include generating one or more data points within the third time period based on the first metric. The method can include generating, based on a model using machine learning and input can include the data points generated within the third time period, one or more data points corresponding to a performance of a second series subsequent to the prediction time stamp. The method can include presenting, via the user interface, a first presentation that indicates the performance of the second series subsequent to the prediction time stamp in a coordinate space including the third time period. The method can include presenting, via the user interface, a second presentation that indicates a region in the coordinate space including the third time period, the region corresponding to the performance of the second series subsequent to the prediction time stamp.

Aspects of this technical solution are directed to a computer readable medium including one or more instructions stored thereon and executable by a processor. The processor can receive, by the processor and via a user interface, an indication of a first series associated with one or more time stamps before a prediction time stamp indicating a start time of a prediction range. The processor can segment, by the processor, a first time period associated with the first series into a second time period bounded by a first time stamp within the first time period and a second time stamp within the first time period and later than the first time stamp, and into a third time period bounded by a third time stamp within the first time period and later than the second timestamp and a fourth time stamp within the first time period and later than the third time stamp. The processor can determine, by the processor, a first metric associated with the third time period and based on one or more first data points of a training data set associated with the first series and having time stamps bounded by the first time stamp and the second time stamp within the second time period. The processor can generate, by the processor, one or more data points within the third time period based on the first metric. The processor can generate, by the processor and based on a model using machine learning and input can include the data points generated within the third time period, one or more data points corresponding to a performance of a second series subsequent to the prediction time stamp. The processor can present, by the processor and via the user interface, a first presentation that indicates the performance of the second series subsequent to the prediction time stamp in a coordinate space including the third time period. The processor can present, by the processor and via the user interface, a second presentation that indicates a region in the coordinate space including the third time period, the region corresponding to the performance of the second series subsequent to the prediction time stamp.

### BRIEF DESCRIPTION OF THE DRAWINGS

These and other aspects and features of the present implementations will become apparent to those ordinarily skilled in the art upon review of the following description of specific implementations in conjunction with the accompanying figures, wherein:

FIG. 1 illustrates a system in accordance with present implementations.

FIG. 2 illustrates an architecture in accordance with present implementations.

FIG. 3 illustrates a historical performance of a series of a model with a first segmentation structure, in accordance with present implementations.

FIG. 4 illustrates a predicted performance of a series of a model based on a first segmentation structure, in accordance with present implementations.

FIG. 5 illustrates a historical performance of a series of a model with a second segmentation structure in accordance with present implementations.

FIG. 6 illustrates a predicted performance of a series of a model based on a first segmentation structure, in accordance with present implementations.

FIG. 7A illustrates historical performances of multiple series of a model in accordance with present implementations.

FIG. 7B illustrates transformed historical performances of multiple series of a model further to the performance of FIG. 7A.

FIG. 8 illustrates a user interface including a historical performance and a predicted performance, in accordance with present implementations.

FIG. 9 illustrates a user interface including a predicted performance in the absence of a historical performance, in accordance with present implementations.

FIG. 10 illustrates a method of segmenting a series of a model, in accordance with present implementations.

FIG. 11 illustrates a method of segmenting a series of a model in accordance with present implementations.

FIG. 12 illustrates a method of generating a predicted performance based of historical performance, in accordance with present implementations.

### DETAILED DESCRIPTION

The present implementations will now be described in detail with reference to the drawings, which are provided as illustrative examples of the implementations to practice the implementations and alternatives. Notably, the figures and examples below are not meant to limit the scope of the present implementations to a single implementation, but other implementations are possible by way of interchange of some or all of the described or illustrated elements. Moreover, where certain elements of the present implementations can be partially or fully implemented using known components, only those portions of such known components that are necessary for an understanding of the present implementations will be described, and detailed descriptions of other portions of such known components will be omitted so as not to obscure the present implementations. Implementations described as being implemented in software should not be limited thereto, but can include implementations implemented in hardware, or combinations of software and hardware, and vice-versa, unless otherwise specified herein. In the present specification, an implementation showing a singular component should not be considered limiting; rather, the present disclosure is intended to encompass other implementations including a plurality of the same component, and vice-versa, unless explicitly stated otherwise herein. Moreover, applicants do not intend for any term in the specification or claims to be ascribed an uncommon or special meaning unless explicitly set forth as such. Further, the present implementations encompass present and future known equivalents to the known components referred to herein by way of illustration.

This technical solution can generate a predicted performance of a target series having a partial or no history. A partial history can correspond to a presence of a subset of data points within time stamps of a particular time period earlier than a prediction time stamp indicating the earliest time stamp of a prediction time period. No history can correspond to a lack of any data points in the particular time period. Thus, this technical solution can provide a technical improvement of generating a predicted performance of a target series independently of any historical data corresponding to the target series. The technical solution can generate a predicted performance of the target series based on historical performance of one or more reference series distinct from the target series. The technical solution can generate imputed data based on segments of reference series over time, and can generate medians or metrics corresponding to aggregate values of reference series within particular segments. The technical solution can impute values for the target series based on the metrics, and can generate a predicted performance based on the imputed values. Thus, this technical solution can provide a technical improvement of generating a predicted performance of a target series having a partial history or no history.

For example, a series can correspond to a number of data points linked with or associated with a particular entity or characteristic over time. For example, a series can corresponding to sales of a particular product at a particular store over a particular time period. For example, a time period can correspond to a span of time greater than one time stamp.

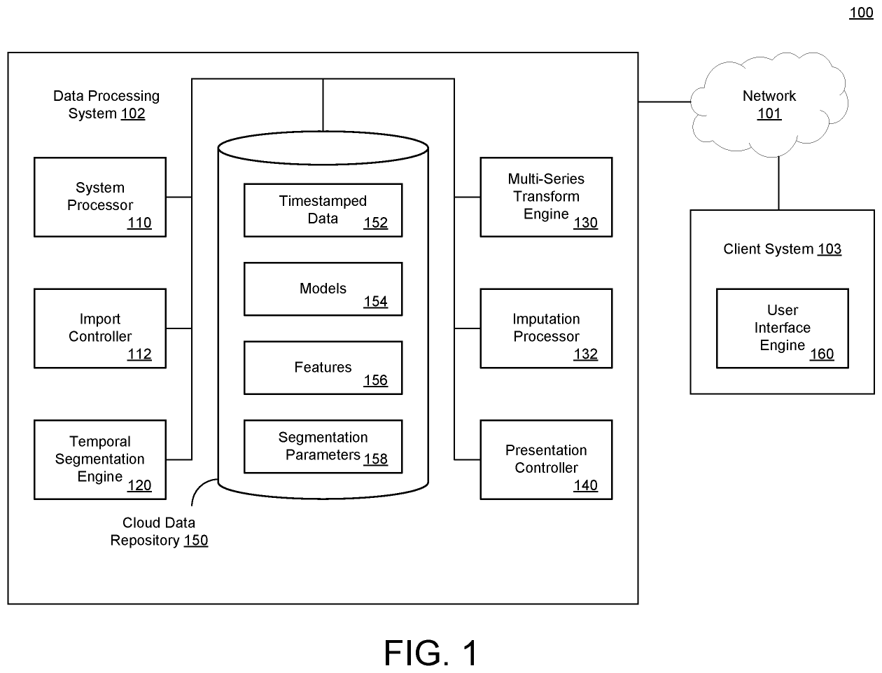

FIG. 1 illustrates an example system in accordance with an implementation. As illustrated by way of example in FIG. 1, an example system 100 can include a network 101, a data processing system 102, and a client computing system 103. The network 101 can be any type or form of network. The geographical scope of the network 101 can vary widely and the network 101 can be a body area network (BAN), a personal area network (PAN), a local-area network (LAN), e.g. Intranet, a metropolitan area network (MAN), a wide area network (WAN), or the Internet. The topology of the network 101 can be of any form and can include, e.g., any of the following: point-to-point, bus, star, ring, mesh, or tree. The network 101 can be an overlay network which is virtual and sits on top of one or more layers of other networks 101. The network 101 can be of any such network topology as known to those ordinarily skilled in the art capable of supporting the operations described herein. The network 101 can utilize different techniques and layers or stacks of protocols, including, e.g., the Ethernet protocol, the internet protocol suite (TCP/IP), the ATM (Asynchronous Transfer Mode) technique, the SONET (Synchronous Optical Networking) protocol, or the SDH (Synchronous Digital Hierarchy) protocol. The TCP/IP internet protocol suite can include application layer, transport layer, internet layer (including, e.g., IPv6), or the link layer. The network 101 can be a type of a broadcast network, a telecommunications network, a data communication network, or a computer network.

The data processing system 102 can include a physical computer system operatively coupled or couplable with the network 101 and the client computing system 103, either directly or directly through an intermediate computing device or system. The data processing system 102 can include a virtual computing system, an operating system, and a communication bus to effect communication and processing. The data processing system can include a system processor 110, an import controller 112, a temporal segmentation engine 120, a multi-series transform engine 130, an imputation processor 132, a presentation controller 140, and a cloud data repository 150. One or more of the components corresponding to the data processing system 102 can include one or more logical or electronic devices including but not limited to integrated circuits, logic gates, flip flops, gate arrays, programmable gate arrays, and the like.

The system processor 110 can execute one or more instructions associated with the system 100. The system processor 110 can include an electronic processor, an integrated circuit, or the like including one or more of digital logic, analog logic, digital sensors, analog sensors, communication buses, volatile memory, nonvolatile memory, and the like. The system processor 110 can include, but is not limited to, at least one microcontroller unit (MCU), microprocessor unit (MPU), central processing unit (CPU), graphics processing unit (GPU), physics processing unit (PPU), embedded controller (EC), or the like. The system processor 110 can include a memory operable to store or storing one or more instructions for operating components of the system processor 110 and operating components operably coupled to the system processor 110. The one or more instructions can include at least one of firmware, software, hardware, operating systems, embedded operating systems, and the like. The system processor 110 or the system 100 generally can include at least one communication bus controller to effect communication between the system processor 110 and the other elements of the system 100. Any electrical, electronic, or like devices, or components associated with the components corresponding to the data processing system 102 can also be associated with, integrated with, integrable with, replaced by, supplemented by, complemented by, or the like, the system processor 110 or any component thereof. The system processor 110 can obtain, by the user interface, a join key identifying the compatible fields. Each of the compatible fields can correspond to a predetermined temporal parameter or a predetermined geographic parameter. The data processing system can obtain, by the user interface, a join key identifying the compatible fields.

The import controller 112 can obtain one or more data sets, models, features, and lag parameters from the cloud data repository 150 or the network 101. For example, the import controller 112 can include one or more of a query processor, a database application programming interface (API), a database translation processor, and a stream processor. The import controller 112 can obtain one or more data sets stored at the cloud data repository 105, or available by a streaming interface connection operable to provide data of a set for an external source within one or more timing or latency constraints. A timing or latency constraint can correspond to a maximum delay between generation of a data point or group of data points and storage of the data point or group of data points at the cloud data repository 150. The import controller 112 can, for example, obtain a data set satisfying one or more particular criteria. The import controller 112 can, for example, obtain a data set having one or more data points or groups of data points satisfying a particular join key, or portion thereof. For example, the import controller 112 can obtain all data rows having timestamps within a particular range, or timestamps matching a predetermined value, label, or any combination thereof.

The temporal segmentation engine 120 can create one or more time periods based on time stamps or time periods corresponding to particular series or groups of series. The temporal segmentation engine can obtain a series and can identify a time boundary associated with the series. A time boundary can correspond to an earliest or a latest time stamp in a particular time period of associated with a particular time period. For example, a time boundary can correspond to an earliest time stamp of a data point in the series or another series, or a predetermined time stamp corresponding to a time stamp boundary associated with or bounding a plurality of series. The temporal segmentation engine 120 can receive one or more indications of segment operations via the user interface engine 160. For example, an indication of a segment operation can include a number of segments into which to divide a time period spanning a particular series or group of series. For example, an indication of a segment operation can include one or more time stamps corresponding to particular points at which to divide a time period into two distinct time periods. The temporal segmentation engine 120 can generate a segmentation option for selection based on one or more characteristics corresponding to a series or group of series. For example, the temporal segmentation engine 120 can determine to segment a series into a particular number of segments or at a particular time stamp based on a characteristic that indicates a distribution of one or more data points within the time period. For example, the temporal segmentation engine 120 can generate segments of time periods each including an equal number of data points or a predetermined number of data points. The temporal segmentation engine 120 can store any segmented series or segmented time periods to the cloud data repository 150.

The multi-series transform engine 130 can modify a distribution of data points of one or more particular series based on a predetermined scalar or a scalar based on one or more series. The multi-series transform engine 130 can identify a median, maximum, and minimum value of a particular series, and can scale one or more data points to correspond to a particular scaled minimum and scaled maximum. The multi-series transform engine 130 can determine a scaled minimum and a scaled maximum based on a particular characteristic of a series. The characteristic can include, for example, a step size associated with a coordinate of the series, or relative to another series or group of series. For example, the multi-series transform engine 130 can expand a series having a high-granularity and low-magnitude distribution into a distribution having a granularity matching a series with low-granularity and high-magnitude. Modifying the distribution of a series can include modifying multiple data series on a per-segment basis, to independently modify portions of series within distinct time periods with scaling that can differ from time period to time period and segment to segment. The multi-series transform engine 130 can increase compatibility of multiple series with the imputation processor 132 by increasing the amount of input data within a corresponding coordinate space, to increase the amount of data available for imputation of series with historical data for generation “cold start” predictive performance. Thus, this technical solution can achieve the technical improvement of increasing accuracy of generating a “cold start” predictive performance by maximizing available input data. The multi-series transform engine 130 can store scaled segment parameters to the cloud data repository 150.

The imputation processor 132 can generate one or more data points or one or more values corresponding to particular data points in a series or group of series. The imputation processor 132 can generate data points having values corresponding to a data type of the series. For example, a series having a data type of numeric values can be imputed with a numeric value. A numeric value can be, for example, a 0, any arithmetic average value of the data points in the series, or a predetermined value corresponding to the series. For example, a series having a data type of categorical values can be imputed with a predetermined categorical value. The imputation processor 132 can select a particular imputation value based on a characteristic of the series or based on an input received via the user interface including a selection of an imputation value. The imputation processor 132 can provide the augmented data set to the presentation controller 140 in whole or in part. The presentation controller 140 can generate instructions to operate, activate, and modify a user interface located locally or remotely from the data processing system 102. The presentation controller 140 can provide, for example, instructions by an API including a data set or portions thereof, features, or portions thereof, models, or portions thereof, and lag parameters, or any portion thereof, or any combination thereof, to the client computing system 103.

The cloud data repository 150 can store data associated with the system 100. The cloud data repository 150 can include one or more hardware memory devices to store binary data, digital data, or the like. The cloud data repository 150 can include one or more electrical components, electronic components, programmable electronic components, reprogrammable electronic components, integrated circuits, semiconductor devices, flip flops, arithmetic units, or the like. The cloud data repository 150 can include at least one of a non-volatile memory device, a solid-state memory device, a flash memory device, and a NAND memory device. The cloud data repository 150 can include one or more addressable memory regions disposed on one or more physical memory arrays. A physical memory array can include a NAND gate array disposed on, for example, at least one of a particular semiconductor device, integrated circuit device, and printed circuit board device. The cloud data repository 150 can include timestamped data storage 152, model storage 154, feature storage 156, and segmentation parameter storage 158.

The timestamped data storage 152 can store data sets having timestamped data points or groups of data points. For example, the data sets can include tabular data including multiple data rows each corresponding to a particular data point, and multiple columns each corresponding to a particular feature corresponding to the data points. For example, each cell in the data set can correspond to a particular feature of a particular data point. Where a cell has a value, the data point have a value corresponding to the feature. The model storage 154 can store models trained by machine learning to execute performance output based on data sets of the timestamped data storage 152. The models can include timestamped data processing features, metrics, weights, filters, or any combination thereof, to generate performances compatible with various temporal properties or lag parameters. The model storage 154 can thus store models with a technical improvement to use machine learning to generate performance output that can create predictions based on varying distances between timestamps in a data set.

The feature storage 156 can store features or groups of features generated by and testable by the multi-series transform engine 130. The feature storage 156 can include a memory space for testing models with composite features and generating augmented data sets for validation against accuracy thresholds. The segmentation parameter storage 158 can store metrics and series corresponding to temporal segmentation and multi-series transforms. For example, the segmentation parameter storage 158 can store timestamps linked with a particular segment that indicate boundaries of particular time periods within a time period corresponding to the series. For example, the segmentation parameter storage 158 can store metrics to scale a particular series with respect to a minimum value, maximum value, or a combination thereof.

The client computing system 103 can include a computing system located remotely from the data processing system 102. The client computing system 103 can include a user interface engine. The user interface engine 160 can present a user interface, including at least a graphical user interface. The user interface engine 160 can be operatively couplable with a display device. The display device can display at least one or more user interface presentations, and can include an electronic display. An electronic display can include, for example, a liquid crystal display (LCD), a light-emitting diode (LED) display, an organic light-emitting diode (OLED) display, or the like. The display device can receive, for example, capacitive or resistive touch input.

The data processing system 102 can detect, based on a number of data points having corresponding time stamps within the first time period, a characteristic indicating a distribution of data points of the first series. The data processing system 102 can select, based on the characteristic indicating the distribution, a segmentation model operable to segment the first series. The data processing system 102 can segment, in accordance with the selected segmentation model, the first time period. The data processing system 102 can provide, via the user interface, a control affordance to receive input indicating the selection of the segmentation model. The characteristic can indicate presence of data points associated with the first series, absence of data points associated with the first series, or partial presence of data points associated with the first series.

The data processing system 102 can generate a first baseline metric associated with a third series of the model and based on one or more data points can include training data of the third series. The data processing system 102 can modify, based on the first baseline metric, values of one or more of the data points corresponding to the performance of the first series. The first baseline metric can correspond to a mean value, a median value, a maximum value, a minimum value, an earliest value, or a latest value of the data points can include training data of the third series. The data processing system 102 can generate a second baseline metric associated with a fourth series of the model and based on one or more data points can include training data of the fourth series. The data processing system 102 can modify, based on a combination of the first baseline metric and the second baseline metric, values of one or more of the data points corresponding to the performance of the second series.

The data processing system 102 can generate, based on one or more second data points of a training data set associated with the first series and having time stamps between or matching the first time stamp and the second time stamp, a second metric associated with the second time period. The first metric corresponding to a mean or median value of the first data points. The data processing system can present, via the user interface and in a coordinate space including the third time period, the performance and a region indicating a confidence interval corresponding to the performance.

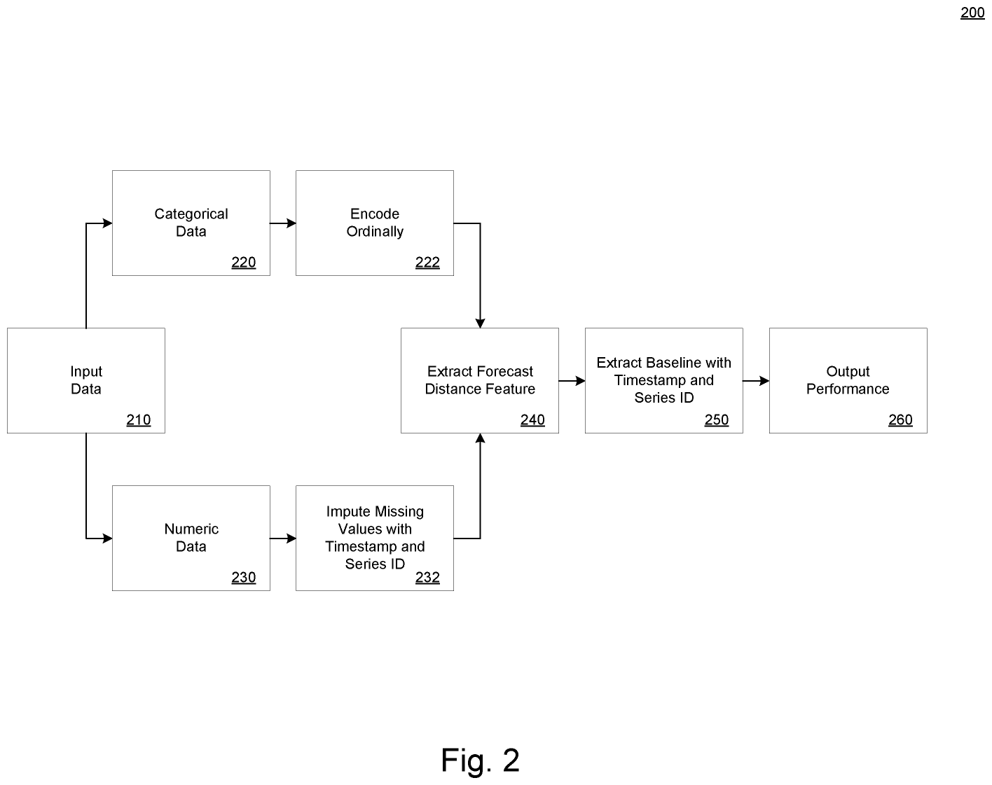

FIG. 2 illustrates an example architecture in accordance with an implementation. As illustrated by way of example in FIG. 2, an example architecture 200 can include an input data stage 210, a categorical data stage 220, an ordinal encoding stage 222, a numeric data stage 230, an imputation stage 232, a forecast distance stage 240, a baseline stage 250, and an output performance stage 260. The example system 100 or any component thereof can execute the architecture 200 according to present implementations.

The input data stage 210 can obtain one or more data points corresponding to particular series or groups of series. The input data stage 210 can identify a data type corresponding to a particular series, and can transmit the data points of a series to the categorical data stage 220 or the numeric data stage 230 in accordance with a determination that the series contains categorical data or numeric data. For example, categorical data can correspond to labels, enumerated variables, or the like. The input data stage 210 can correspond at least partially in one or more of structure and operation to the import controller 112.

The categorical data stage 220 can process features having values corresponding to categorical values. The categorical data stage 220 can identify particular categories or labels compatible with particular features, based on existing labels within that feature assigned to particular data points of a series including the feature. For example, the categorical data stage 220 can identify in a feature corresponding to “temperature” with existing fields for “hot” and “cold” and can create an association between the features and the existing fields. The categorical data stage 220 can identify particular categories or labels compatible with particular features, based on one or more heuristics corresponding to the feature. For example, the categorical data stage 220 can detect that a feature is associated with two existing fields, and can create an “average,” “default” or “quantum” state to augment a binary classification. For example, the feature corresponding to “temperature” can have a “default” value added to support an inference of a “lukewarm” state. Thus, the categorical data stage 220 can provide a technical improvement of generating categorical states for particular features that can provide higher granularity to imputation of input data structures including categorical feature.

The ordinal encoding stage 222 can generate imputations corresponding to particular values of features across data points. The ordinal encoding stage 222 can impute a particular categorical value to a particular data point, by identifying a particular feature of a particular data point, and by storing a value to a coordinate or cell of a data point corresponding to the feature. The ordinal encoding stage 222 can select a particular categorical value for storing, and can obtain a selection of a categorical value for storing via a user interface. For example, the ordinal encoding stage 222 can identify one of a “hot,” “cold” and “average” value for a feature corresponding to “temperature” as an imputation category, and can store that value to each field of the feature not having a value. For example, the ordinal encoding stage 222 can select “hot” or “cold” in response to a determination to skew imputation toward a particular existing feature, and can select “hot” in response to a determination to impute neutrally with respect to existing features. Thus, the ordinal encoding stage 222 can provide a technical improvement of providing imputation at a high level of granularity with respect to particular non-numeric features.

The numeric data stage 230 can process features having values corresponding to numeric values, scalar values, ordered values, or any combination thereof. The numeric data stage 230 can identify particular quantities or ranges of quantities compatible with particular features, based on existing quantities within that feature assigned to particular data points of a series including the feature. For example, the numeric data stage 230 can identify in a feature corresponding to “temperature” with existing fields for “101.3” and “−66.3” and can create an association between the features and the existing fields. The numeric data stage 230 can identify particular ranges of quantities compatible with particular features, based on one or more heuristics corresponding to the feature. For example, the categorical data stage 220 can detect that a feature is associated with integers, and can create an “e,” “0” or “−1” state to fill in an integer range. For example, the feature corresponding to “temperature” can have a “0” value added to support an inference of a “lukewarm” state. For example, the feature corresponding to “temperature” can have an “e” value added to support an inference of a “lukewarm” state with a number unlikely to be present in input data and thus identifiable as an imputed value. Thus, the numeric data stage 230 can provide a technical improvement of generating numeric ranges for particular features that can provide higher granularity to imputation of input data structures including categorical feature.

The imputation stage 232 can generate imputations corresponding to particular values of features across data points. The imputation stage 232 can impute a particular numeric value or the like to a particular data point, by identifying a particular feature of a particular data point, and by storing a value to a coordinate or cell of a data point corresponding to the feature. The imputation stage 232 can select a particular numeric value for storing, and can obtain a selection of a numeric value for storing via a user interface. For example, the ordinal encoding stage 222 can identify a range between “−76.9” and “135.9” for a feature corresponding to “temperature” as an imputation category, and can store that value to each field of the feature not having a value. For example, the imputation stage 232 can select “e” in response to a determination to skew imputation at the expense of identifying imputed values, and can select an arithmetic mean or median across the range or the set of data points in the range, in response to a determination to impute neutrally with respect to existing features. Thus, the imputation stage 232 can provide a technical improvement of providing imputation at a high level of granularity with respect to particular numeric features.

The forecast distance stage 240 can generate a prediction time stamp corresponding to an earliest time at which to generate a predicted performance of a model. The forecast distance stage 240 can generate the prediction time stamp in response to a determination based on a characteristic of imputation of one or more features associated with one or more series. For example, the forecast distance stage 240 can generate a prediction time stamp corresponding to a time a minimum distance subsequent to a time stamp in which a particular threshold number or percentage of value are available. For example, the forecast distance stage 240 can generate a prediction time stamp corresponding to a time at least 7 days after a latest timestamp having at least 75% of its feature values available. For example, the forecast distance stage 240 can generate a prediction time stamp corresponding to a time at least 7 days after at least 5 consecutive latest timestamps having at least 75% of its feature values available. Thus, the forecast distance stage 240 can provide a technical improvement higher accuracy of predicted performance of a model, based on generating a prediction performance based on imputed data of a threshold of availability of input data.

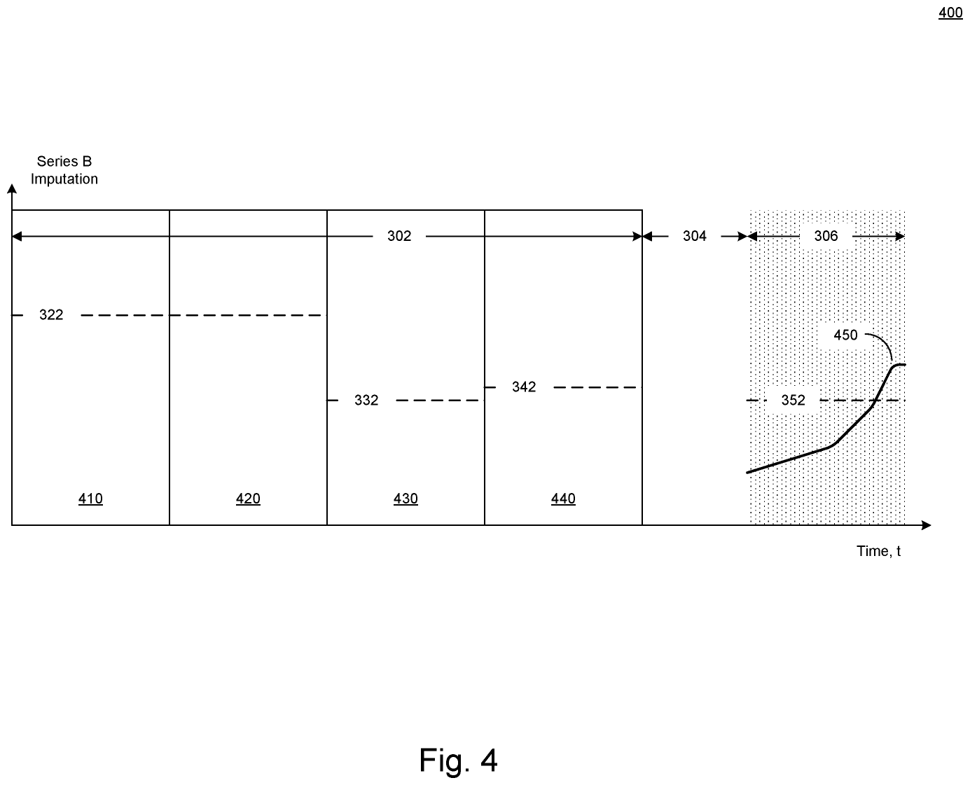

The baseline stage 250 can generate transformations of particular series based on various distribution characteristics of the series. For example, the baseline stage 250 can generate a transformation of a series based on one or more of a minimum, maximum, and median of a particular series. The minimum or maximum can, for example, correspond to a local minim or local maximum within a particular segment of the series. The baseline stage 250 can receive one or more time stamps indicating particular boundaries corresponding to particular time periods of a series, and can perform a transformation on one or more segments of a series and one or more series separately or in subsets. For example, the baseline stage 250 can perform one or more transformations of one or more series in accordance with operation of the multi-series transform engine 130. The output performance stage 260 can generate a predicted performance for a particular series based on the baselines generated by the baseline stage 250. For example, the output performance stage 260 can generate a predicted performance from a prediction time stamp generated by the forecast distance stage 240. The output performance stage 260 can generate a predicted performance in accordance with the performances of FIGS. 4, 6, and 7B, for example.

The architecture 200 or any portion thereof can be implemented on, for example, a non-transitory computer readable medium or a plurality thereof. The computer readable medium can include, for example, the cloud data repository 150 or a portable memory device. The computer readable medium can include instructions executable by the processor to detect, by the processor and based on a number of data points having corresponding time stamps within the first time period, a characteristic indicating a distribution of data points of the first series. The processor can provide, by the processor and via the user interface, a control affordance to receive input indicating the selection of the segmentation model. The processor can select, by the processor and based on the characteristic indicating the distribution, a segmentation model operable to segment the first series. The processor can segment, by the processor and in accordance with the selected segmentation model, the first time period.

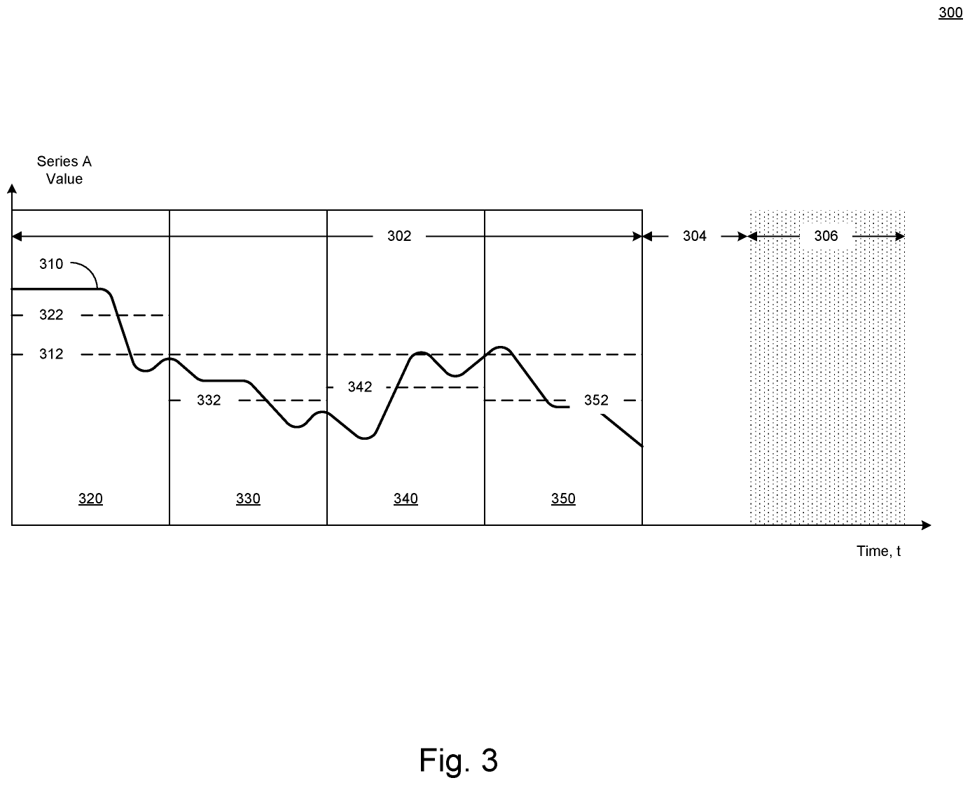

FIG. 3 illustrates a historical performance of a series of a model with a first segmentation structure, in accordance with present implementations. As illustrated by way of example in FIG. 3, an example performance 300 can include a series time period 302, a forecast gap time period 304, a prediction time period 306, and a series 310. The series time period 302 can include first, second, third and fourth time periods 320, 330, 340 and 350. The series 310 can have a series median 312, and first, second, third and fourth segment medians 322, 332, 342 and 352.

The series time period 302 can correspond to a time period including data points of a series. The series time period 302 can correspond to a time period before a prediction time stamp. The series time period 302 can correspond to a time period before a current time stamp corresponding to a current time. The forecast gap time period 304 can correspond to a time period between the series time period 302 and the prediction time period 306. The forecast gap time period 304 can correspond to a time period later than the series time period 302 and earlier than the prediction time period 306. The forecast gap time period 304 can correspond to a minimum time period between a latest data point of the series 310 and an earliest data point that can be predicted. The forecast gap time period 304 can be bounded at a latest edge by a prediction time stamp and at an earliest edge by the series time period 302. The prediction time period 306 can correspond to a time period including time stamps corresponding to data points of a predictive performance. The prediction time period 306 can be bounded at an earliest edge by the forecast gap time period 304. The prediction time period 306 can be bounded at a latest edge by a predetermined time stamp or can be unbounded by having no latest time stamp.

The series 310 can include one or more data points each having a time stamp and one or more values corresponding, for example to a coordinate. A series can include a plurality of data points each defined values based on one or more features. Each feature can, for example, correspond to a coordinate in a coordinate space. Thus, for example, a series having a time stamp and a single feature corresponding to “temperature” can correspond to a two-dimensional coordinate having a time value in a time axis and a temperature value in a temperature axis. The series 310 can include any number of data points and any number of features, and thus can correspond to a coordinate space having any number of dimensions each corresponding to a particular feature of the series. The series median 312 can include a metric corresponding to an aggregation of one or more values of one or more features of various data points. For example, the series median 312 can be based on an arithmetic median of all values of a particular feature in the series time period 302. An aggregation can correspond to an operation to combine a plurality of features over time into a single scalar value. For example, the series median 312 can correspond to a centroid of a multidimensional coordinate space corresponding to a plurality of data points, where the data points include values for a plurality of features in the multidimensional coordinate space. Thus, the series median 312 can, for example, correspond to an aggregation other than or including as a component there a median, mean, mode of a plurality of data points with respect to one or more features of the data points.

The first, second, third and fourth time periods 320, 330, 340 and 350 can correspond to segmented time periods within the series time period 302. The first time period 320 can be earlier than the second time period 330. The second time period 330 can be earlier than the third time period 340. The third time period 340 can be earlier than the fourth time period 350. A time range of the first, second, third and fourth time periods 320, 330, 340 and 350 can be equal. The first, second, third and fourth segment medians 322, 332, 342 and 352 include metrics respectively corresponding to an aggregation of one or more values of one or more features of various data points within respective ones of the first, second, third and fourth time periods 320, 330, 340 and 350. Thus, the first, second, third and fourth segment medians 322, 332, 342 and 352 can correspond to aggregations within the smaller first, second, third and fourth segment medians 322, 332, 342 and 352 as compared to the first time period 302, to provide first, second, third and fourth segment medians 322, 332, 342 and 352 more accurate to the data points within the particular segmented time period.

FIG. 4 illustrates a predicted performance of a series of a model based on a first segmentation structure, in accordance with present implementations. As illustrated by way of example in FIG. 4, an example performance 400 can include the series time period 302, the forecast gap time period 304, the prediction time period 306, the first, second, third and fourth segment medians 322, 332, 342 and 352, first, second, third and fourth time periods 410, 420, 430 and 440, and a prediction performance 450.

The first, second, third and fourth time periods 410, 420, 430 and 440 can correspond to segmented time periods within the series time period 302 that correspond to a series with partial history or no history. The first, second, third and fourth time periods 410, 420, 430 and 440 correspond to the first, second, third and fourth time periods 320, 330, 340 and 350 that correspond to a series distinct form the series with partial history or no history. The first, second, third and fourth time periods 410, 420, 430 and 440 can be linked with various combination of first, second, third and fourth segment medians 322, 332 and 342 to support a predictive imputation of the series with partial history or no history. For example, each of the second, third and fourth time periods 420, 430 and 440 can be linked with the first, second and third time median 322, 332 and 342. This way, each of the second, third and fourth time periods 420, 430 and 440 is linked with the median of the preceding time period corresponding to another series. Thus, this technical solution provides a technical improvement of providing more granular time-based imputation framework based on applying the preceding median of a particular segment to an imputation process and a prediction process for a series with partial history or no history. The first time period 410 can be linked with the first segment median 322 because it is the earliest segment median. The prediction time period 306 can be linked with the fourth segment median 352 because the fourth segment median is the latest segment median prior to the prediction time period 306. The prediction performance 450 can be based on imputed values of the series having partial history or no history based on the segment medians linked with their corresponding time periods. The prediction performance 450 can be based on existing values of various data points of the series having partial history, in addition to the imputed values based on the segmented medians.

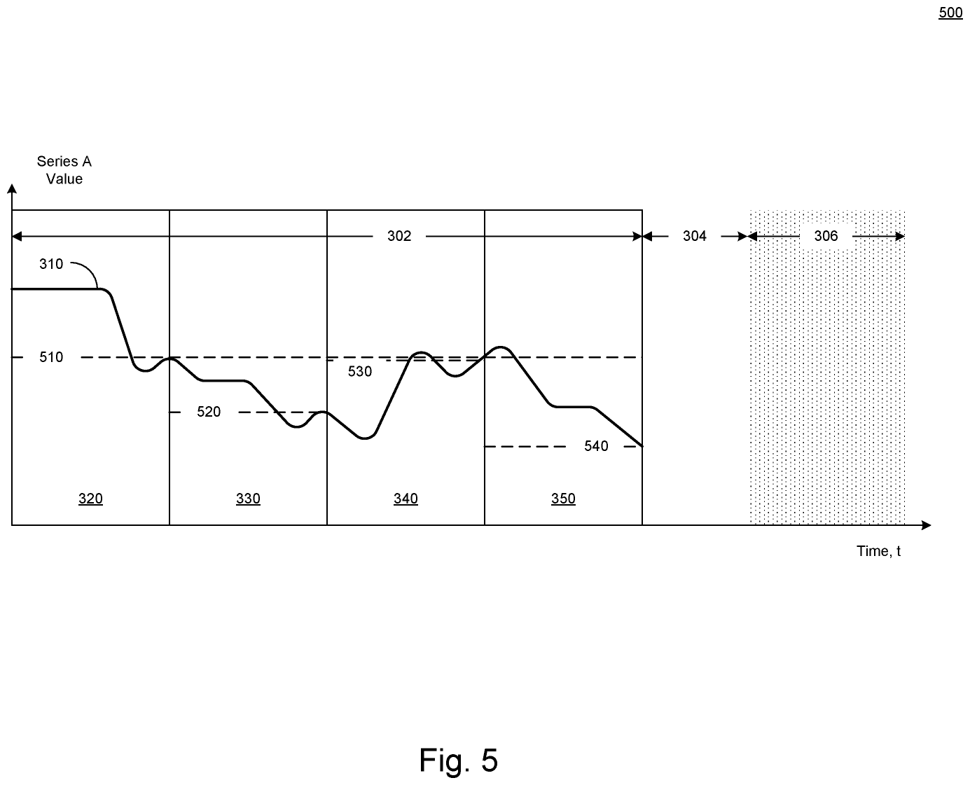

FIG. 5 illustrates a historical performance of a series of a model with a second segmentation structure in accordance with present implementations. As illustrated by way of example in FIG. 5, an example performance 500 can include the series time period 302, the forecast gap time period 304, the prediction time period 306, and the series 310. The series time period 302 can include the first, second, third and fourth time periods 320, 330, 340 and 350. The series 310 can have first, second, third and fourth segment terminal values 510, 520, 530 and 540.

The first, second, third and fourth segment terminal values 510, 520, 530 and 540 can correspond to a final or latest value of a data point in a particular one of the first, second, third and fourth time periods 320, 330, 340 and 350. Thus, the performance can be based on a latest value for one or more of the time periods. The architecture can advantageously select a median or a latest value for various time periods. For example, the first time period 320 can be linked with a segment terminal value and the second time period 330 can be linked with a segment median value.

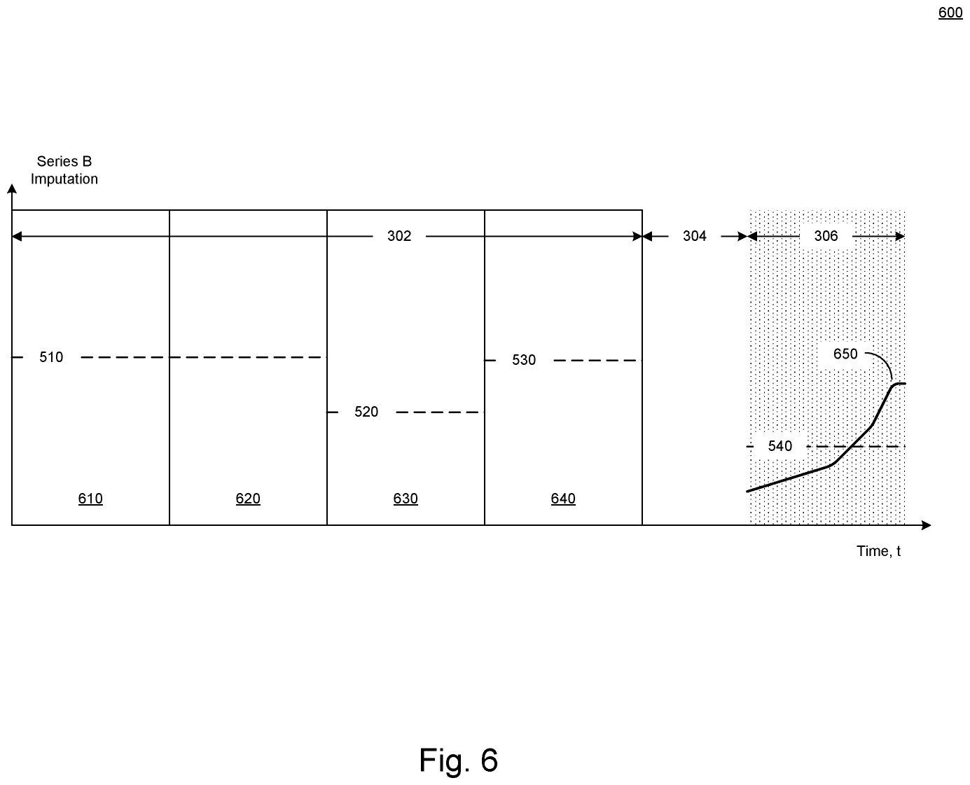

FIG. 6 illustrates a predicted performance of a series of a model based on a first segmentation structure, in accordance with present implementations. As illustrated by way of example in FIG. 6, an example performance 600 can include the series time period 302, the forecast gap time period 304, the prediction time period 306, first, second, third and fourth time periods 610, 620, 630 and 640, and the first, second, third and fourth segment terminal values 510, 520, 530 and 540, a prediction performance 650.

The first, second, third and fourth time periods 610, 620, 630 and 640 can be linked with various combination of first, second, third and fourth segment terminal values 510, 520, 530 and 540 to support a predictive imputation of the series with partial history or no history. For example, each of the second, third and fourth time periods 620, 630 and 640 can be linked with the first, second and third segment terminal values 510, 520 and 530 This way, each of the second, third and fourth time periods 620, 630 and 640 is linked with the terminal value of the preceding time period corresponding to another series. Thus, this technical solution provides a technical improvement of providing more granular time-based imputation framework based on applying the preceding terminal value of a particular segment to an imputation process and a prediction process for a series with partial history or no history. The terminal value can be advantageous for data sets having a high degree of variable between maxima and minima that may reduce the reliability of an arithmetic aggregation within that time period.

The first time period 610 can be linked with the first segment terminal value 510 because it is the earliest segment terminal value. The prediction time period 306 can be linked with the fourth segment terminal value 540 because the fourth segment terminal value is the latest segment median prior to the prediction time period 306. The prediction performance 650 can be based on imputed values of the series having partial history or no history based on the segment terminal values linked with their corresponding time periods. The prediction performance 650 can be based on existing values of various data points of the series having partial history, in addition to the imputed values based on the segmented terminal values.

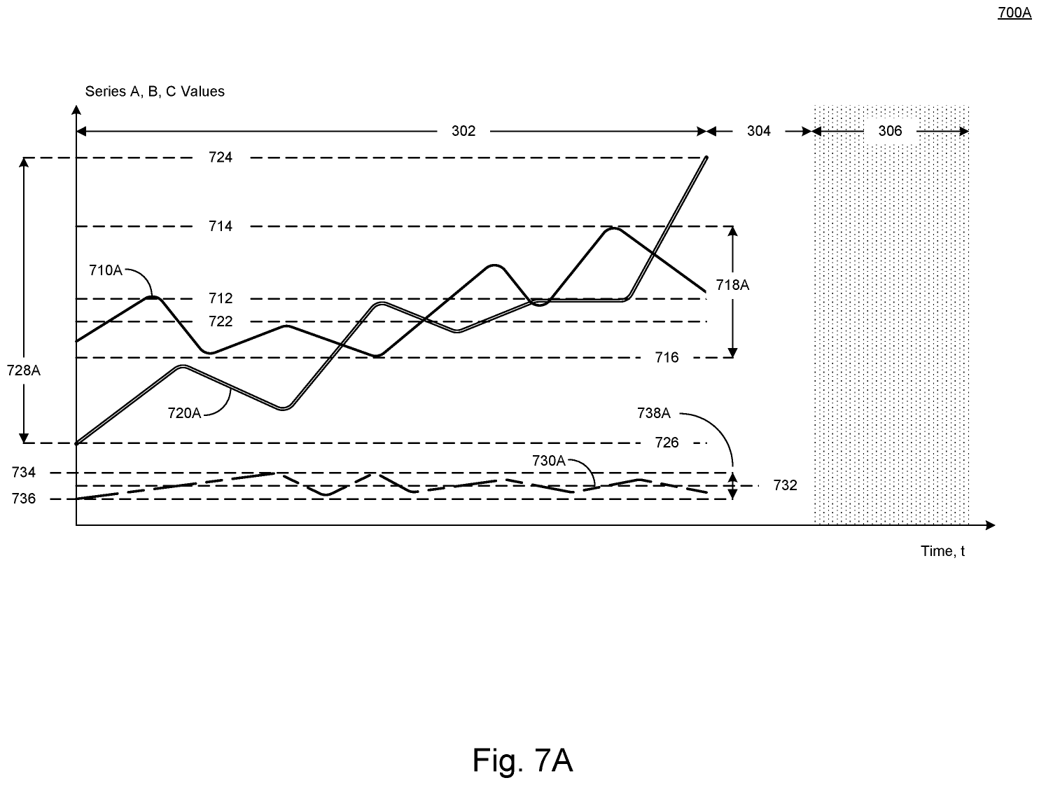

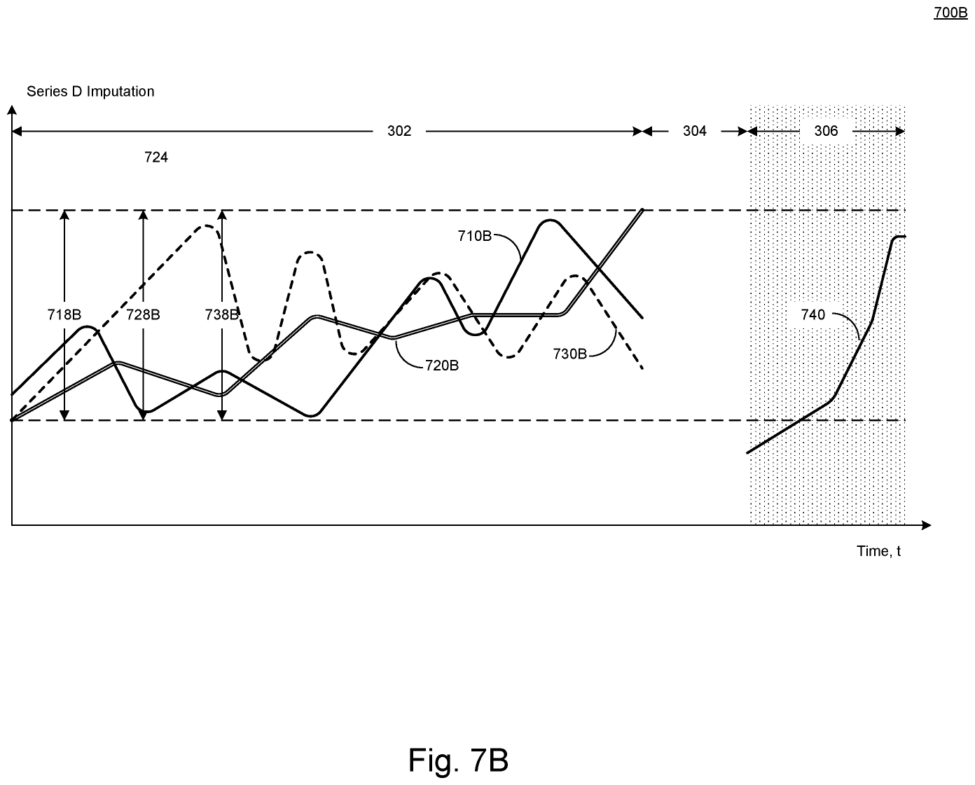

FIG. 7A illustrates historical performances of multiple series of a model in accordance with present implementations. As illustrated by way of example in FIG. 7A, an example multi-series performance 700A can include the series time period 302, the forecast gap time period 304, the prediction time period 306, a first series 710A, a second series 720A and a third series 730A.

The first series 710A can correspond to a first set of data points corresponding to a first set of historical data. For example, the first series 710A can correspond to sales of a particular widget at a store at a first address. The first series 710A can include a median 712, a maximum 714, a minimum 716, and a distribution range 718A. The maximum 714 and the minimum 716 can correspond to largest and smallest values in a coordinate space of a feature or aggregation of features of the first series 710A. The distribution range 718A can correspond to a region including an upper boundary and a lower boundary based respectively on the maximum 714 and the minimum 716.

The second series 720A can correspond to a second set of data points corresponding to a second set of historical data. For example, the second series 720A can correspond to revenue of a particular widget at a store at a second address. The second series 720A can include a median 722, a maximum 724, a minimum 726, and a distribution range 728A. The maximum 724 and the minimum 724 can correspond to largest and smallest values in a coordinate space of a feature or aggregation of features of the second series 720A. The distribution range 728A can correspond to a region including an upper boundary and a lower boundary based respectively on the maximum 724 and the minimum 726.

The third series 730A can correspond to a third set of data points corresponding to a third set of historical data. For example, the third series 730A can correspond to attendance at a store at a first address. The third series 730A can include a median 732, a maximum 734, a minimum 736, and a distribution range 738A. The maximum 734 and the minimum 736 can correspond to largest and smallest values in a coordinate space of a feature or aggregation of features of the third series 730A. The distribution range 738A can correspond to a region including an upper boundary and a lower boundary based respectively on the maximum 734 and the minimum 736. The medians 712, 722 and 732 can correspond to any aggregation as discussed herein, and are not limited to an arithmetic median. The medians 712, 722 and 732, the maxima 714, 724, and 734, and the minima 716, 726 and 736 can be based on values across the entirety of the time period 302, or can be based on any portion of the time period 302 selected by the multi-series transform engine 130.

FIG. 7B illustrates transformed historical performances of multiple series of a model further to the performance of FIG. 7A. As illustrated by way of example in FIG. 7B, an example performance 700B can include the series time period 302, the forecast gap time period 304, the prediction time period 306, a transformed first series 710B, a transformed second series 720B a transformed third series 730B, and a prediction performance 740. The multi-series transform engine 130 can transform the first series 710A, the second series 720A, and the third series 730A into the transformed first series 710B, the transformed second series 720B and the transformed third series 730B by modifying one or more data points of the first series 710A, the second series 720A, and the third series 730A. The multi-series transform engine 130 can scale each of the first series 710A, the second series 720A, and the third series 730A to have a common maximum and common minimum, for example. The multi-series transform engine 130 can scale each of the first series 710A, the second series 720A, and the third series 730A to have distinct and compatible maxima and minima satisfying a predetermined threshold range of each other. For example, the multi-series transform engine 130 can scale each of the first series 710A, the second series 720A, and the third series 730A to be have a maximum change in maximum or minimum of 10%, or a maximum difference between maxima and minima of the first series 710A, the second series 720A, and the third series 730A to satisfying a 20% threshold. The transformed ranges 718B, 728B and 738B can correspond to the ranges of the transformed first, second and third series 710B, 720B and 730B. For example, the multi-series transform engine 130 can generate the transformed first series 710B, the transformed first series 710B, and the transformed first series 710B as a preprocessing step at the numeric data stage 230.

The prediction performance 740 can be based on imputed values of the series having partial history or no history based on the segment terminal values linked with their corresponding time periods. The prediction performance 740 can be based on existing values of various data points of the series having partial history, in addition to the imputed values based on the segmented terminal values, including, for example at least one of the transformed first series 710B, the transformed second series 720B, and the transformed third series 730B.

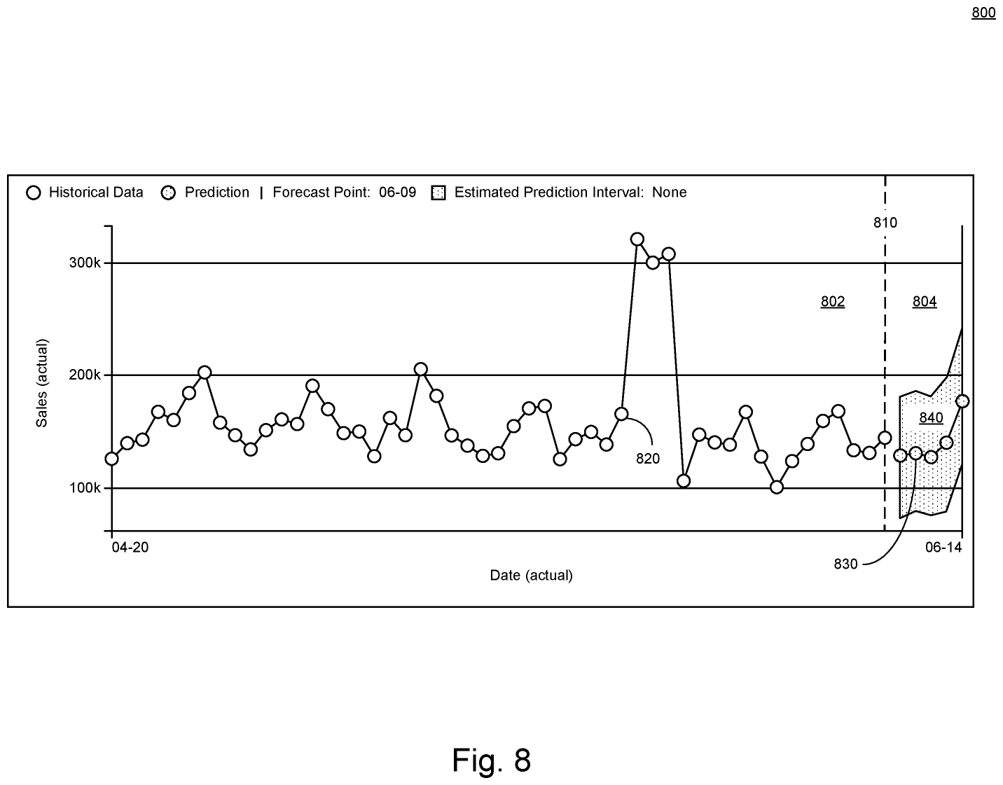

FIG. 8 illustrates a user interface including a historical performance and a predicted performance, in accordance with present implementations. As illustrated by way of example in FIG. 8, an example user interface 800 can include a historical range presentation 802, a prediction presentation 804, a prediction time presentation 810, a plurality of historical data points 820, a plurality of prediction data points 830, and a confidence presentation 840.

The historical range presentation 802 can correspond to a time period bounding data points that can be received as input to generate a predicted performance. The historical range presentation 802 can include the historical data points 820. The historical data points 820 can correspond to data points of a first series and can be presented in a coordinate space visualizing one or more features of the series as axes, colorations, annotations, or any combination thereof. The prediction presentation 804 can correspond to a time period including the prediction time period 306. The prediction time presentation 810 can correspond to a prediction time stamp and can indicate visually an earliest time of the prediction time period 306.

The prediction data points 830 can correspond to data points of a second series having a partial or no history and can be presented in a coordinate space visualizing one or more features of the series as axes, colorations, annotations, or any combination thereof. The confidence presentation 840 can include a region indicating a particular confidence level for the prediction data points 830. For example, the confidence presentation 840 can include a shaded or colorized region indicating a particular confidence interval corresponding to a particular data point or group of data points. The confidence interval can be based on a particular time stamp of a particular data point among the prediction data points 830 or a time range corresponding to a plurality of the prediction data points 830. For example, the confidence interval can indicate a confidence for time stamps between particular data points of the prediction data points 830.

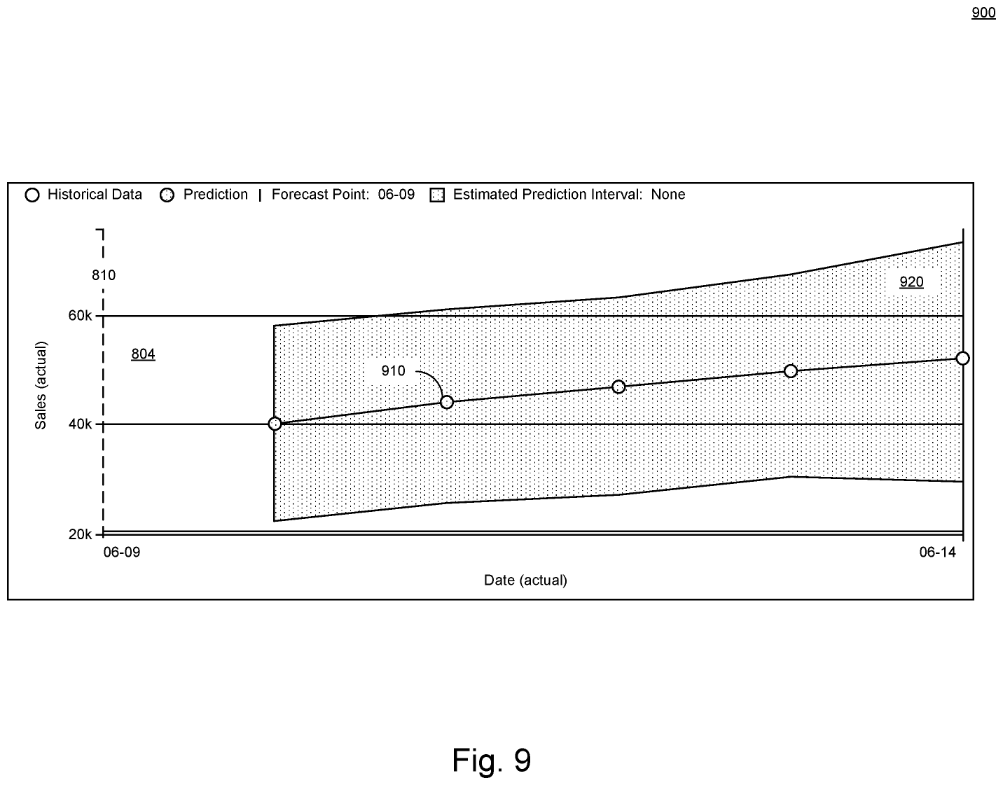

FIG. 9 illustrates a user interface including a predicted performance in the absence of a historical performance, in accordance with present implementations. As illustrated by way of example in FIG. 9, an example user interface 900 can include the prediction presentation 804, a prediction time presentation 810, a plurality of prediction data points 910, and a confidence presentation 920. The user interface can include a presentation directed exclusively to presenting the plurality of prediction data points 910 and the confidence presentation 920 at a higher level of granularity, by presenting only a time period having the prediction time presentation 810 as the earliest time stamp. Thus, this technical solution can provide at least a technical improvement of a user interface to present one or more presentations indicative of particular quantitative properties of a prediction for a given data series over time, in the absence of historical data corresponding to that given data series.

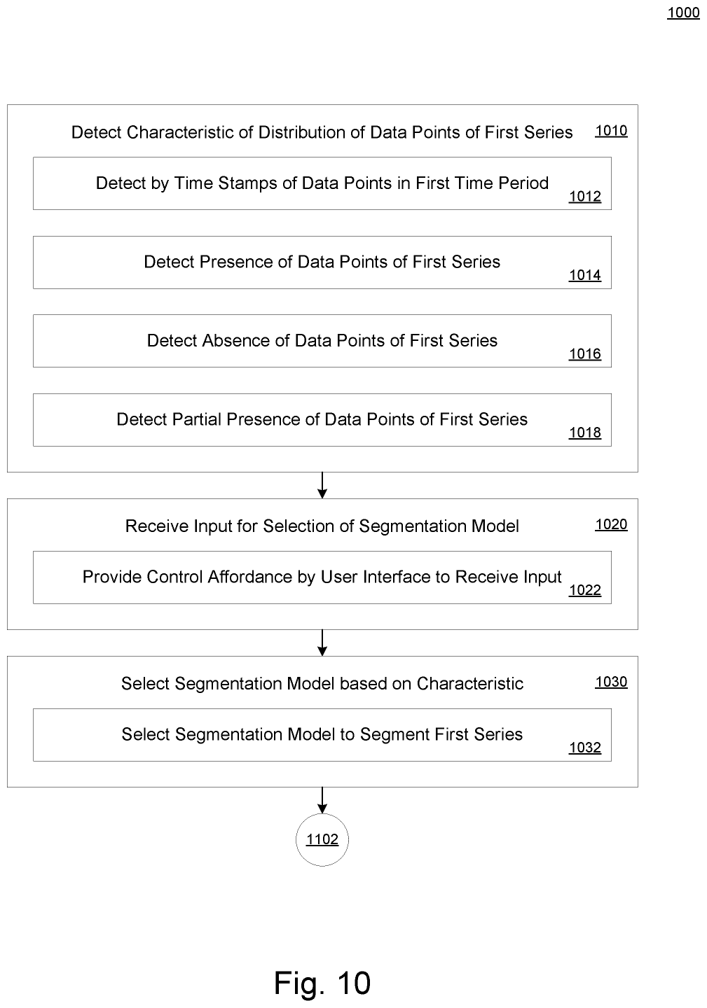

FIG. 10 illustrates a method of segmenting a series of a model, in accordance with present implementations. At least one of the system 100, the architecture 200 and the user interfaces 800 and 900 can perform at least a portion of method 1000 according to present implementations. The method 1000 can begin at 1010.

At 1010, the method can detect a characteristic of a distribution of one or more data points of a first series. For example, the method can include detecting, based on a number of data points having corresponding time stamps within the first time period, a characteristic indicating a distribution of data points of the first series according to presence of data points associated with the first series, absence of data points associated with the first series, or partial presence of data points associated with the first series. 1010 can include at least one of 1012, 1014, 1016 and 1018. At 1012, the method can detect a characteristic of a distribution of one or more data points of a first series by one or more time stamps of data points in a first time period. At 1014, the method can detect presence of one or more data points of a first series. At 1016, the method can detect absence of one or more data points of a first series. At 1018, the method can detect partial presence of one or more data points of a first series. The method 1000 can then continue to 1020.

At 1020, the method can receiving input corresponding to a selection of a segmentation model. 1020 can include 1022. At 1022, the method can provide a control affordance by a user interface to receive input. For example, the method can include providing, via the user interface, a control affordance to receive input indicating the selection of the segmentation model. The method 1000 can then continue to 1030. At 1030, the method can select a segmentation model based on the characteristic. For example, the method can include selecting, based on the characteristic indicating the distribution, a segmentation model operable to segment the first series. 1030 can include 1032. At 1032, the method can select a segmentation model to segment the first series. The method 1000 can then continue to 1102.

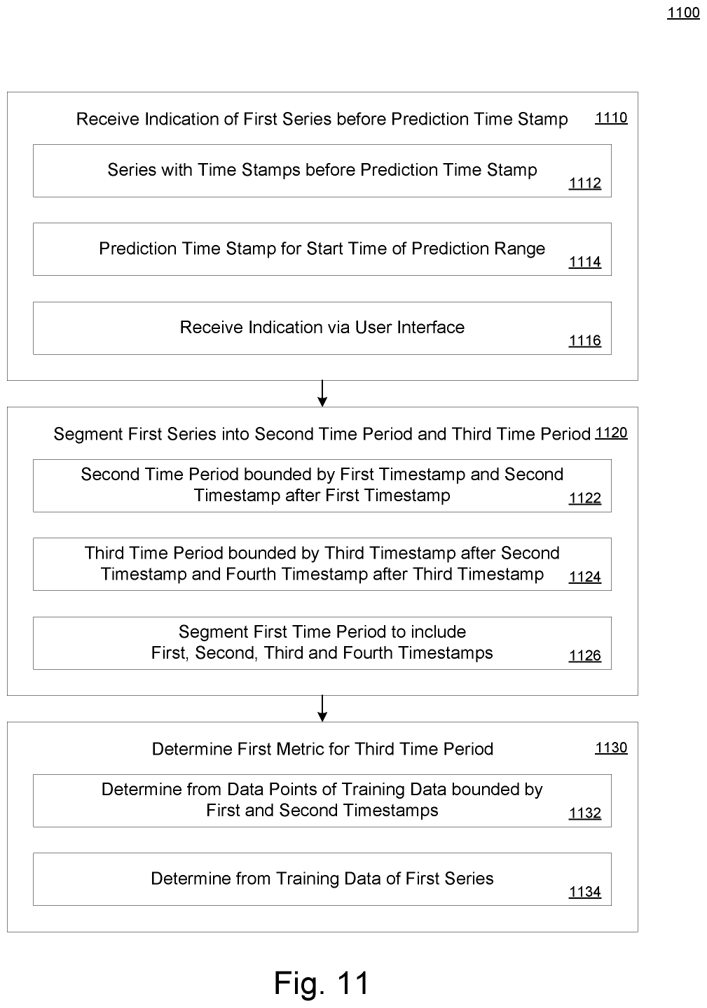

FIG. 11 illustrates a method of segmenting a series of a model in accordance with present implementations. At least one of the system 100, the architecture 200 and the user interfaces 800 and 900 can perform at least a portion of method 1100 according to present implementations.

At 1110, the method can receive an indication corresponding to a first series before a prediction time stamp. 1110 can include at least one of 1112, 1114 and 1116. At 1112, the method can receive an indication corresponding to a first series corresponding to time stamps before a prediction time stamp. At 1114, the method can receive an indication corresponding to a first series before a prediction time stamp corresponding to a start time of a prediction range. At 1116, the method can receive an indication by a user interface.

At 1120, the method can segment the first series into a second time period and a third time period. For example, the method can include segmenting, in accordance with the selected segmentation model, the first time period. 1120 can include at least one of 1122, 1124 and 1126. At 1122, the method can segment the first series into a second time period bounded by a first time stamp and a second time stamp later than the first time stamp. For example, a time stamp later than another time stamp can correspond to a time stamp corresponding to a time, date, or any combination thereof, after or subsequent to the other time stamp. At 1124, the method can segment the first series into a third time period bounded by a third time stamp later than the second time stamp and a fourth time stamp later than the third time stamp. At 1126, the method can segment the first time period to include one or more of the first, second, third and fourth time stamps.

At 1130, the method can determine a first metric corresponding to the third time period. 1130 can include at least one of 1132 and 1134. At 1132, the method can determine a first metric corresponding to the third time period based on one or more data points of training data bounded by the first and second time stamps. At 1134, the method can determine a first metric corresponding to the third time period based on training data corresponding to the first series.

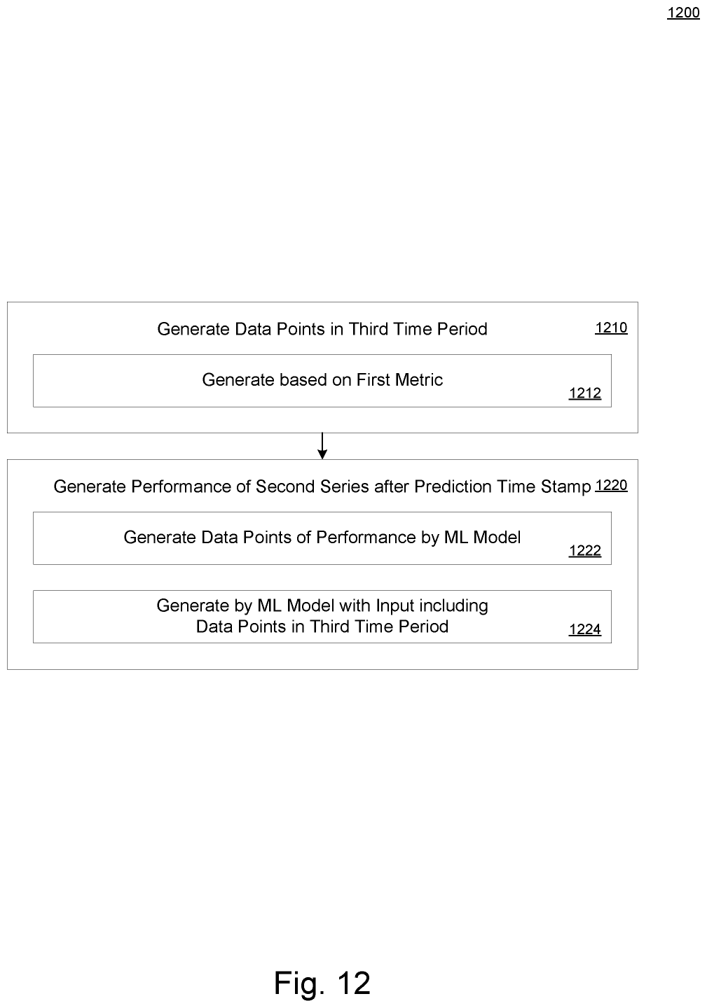

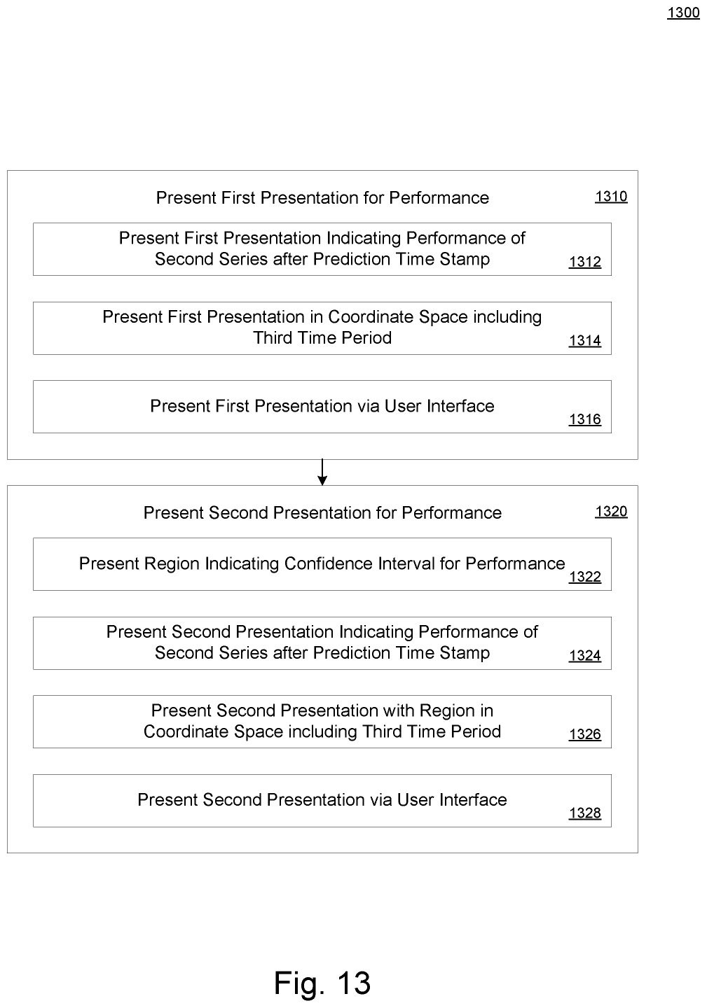

FIG. 12 illustrates a method of generating a predicted performance based of historical performance, in accordance with present implementations. At least one of the system 100, the architecture 200 and the user interfaces 800 and 900 can perform at least a portion of method 1200 according to present implementations.

At 1210, the method can generate one or more data points in a third time period. For example, the method can include generating, based on one or more second data points of a training data set associated with the first series and having time stamps between or matching the first time stamp and the second time stamp, a second metric associated with the second time period. 1210 can include 1212. At 1212, the method can one or more data points in a third time period based on the first metric.

At 1120, the method can generate a performance of a second series after the prediction time stamp. 1220 can include at least one of 1222 and 1224. At 1222, the method can generate one or more data points corresponding to the performance by a machine learning model. At 1224, the method can generate a performance of a second series after the prediction time stamp by a machine learning model with input including data points in a third time period.

FIG. 13 illustrates a method of presenting a predicted performance based of historical performance, in accordance with present implementations. At least one of the system 100, the architecture 200 and the user interfaces 800 and 900 can perform at least a portion of method 1300 according to present implementations.

At 1310, the method 1300 can present a first presentation corresponding to the performance. 1310 can include at least one of 1312, 1314 and 1316. At 1312, the method 1300 can present a first presentation indicating performance of a second series after a prediction time stamp. At 1314, the method 1300 can present a first presentation in a coordinate space including a third time period. At 1316, the method 1300 can present a first presentation via a user interface.

At 1320, the method 1300 can present a second presentation corresponding to the performance. 1320 can include at least one of 1322, 1324, 1326 and 1328. At 1322, the method 1300 can present a region indicating a confidence interval for the performance. At 1324, the method 1300 can present a second presentation indicating a performance of a second series after a prediction time stamp. At 1326, the method 1300 can present a second presentation with a region in a coordinate space including the third time period. At 1328, the method 1300 can present a second presentation via a user interface.

At 1230, the method can present a performance in a coordinate space corresponding to the third time period. 1230 can include at least one of 1232 and 1234. At 1232, the method can present a region indicting a confidence interval corresponding to the performance. At 1234, the method can present a performance in a coordinate space corresponding to the third time period via a user interface. For example, the method can include presenting, via the user interface and in a coordinate space including the third time period, the performance and a region indicating a confidence interval corresponding to the performance.

The method can include generating a first baseline metric associated with a third series of the model and based on one or more data points can include training data of the third series. The method can include modifying, based on the first baseline metric, values of one or more of the data points corresponding to the performance of the first series, the first metric corresponding to a mean or median value of the first data points, and the first baseline metric corresponding to a mean value, a median value, a maximum value, a minimum value, an earliest value, or a latest value of the data points can include training data of the third series. The method can include generating a second baseline metric associated with a fourth series of the model and based on one or more data points can include training data of the fourth series. The method can include modifying, based on a combination of the first baseline metric and the second baseline metric, values of one or more of the data points corresponding to the performance of the second series.

The herein described subject matter sometimes illustrates different components contained within, or connected with, different other components. It is to be understood that such depicted architectures are illustrative, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably couplable,” to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.).

Although the figures and description may illustrate a specific order of method steps, the order of such steps may differ from what is depicted and described, unless specified differently above. Also, two or more steps may be performed concurrently or with partial concurrence, unless specified differently above. Such variation may depend, for example, on the software and hardware systems chosen and on designer choice. All such variations are within the scope of the disclosure. Likewise, software implementations of the described methods could be accomplished with standard programming techniques with rule-based logic and other logic to accomplish the various connection steps, processing steps, comparison steps, and decision steps.

It will be further understood by those within the art that if a specific number of an introduced claim recitation is intended, such an intent will be explicitly recited in the claim, and in the absence of such recitation, no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations).

Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general, such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

Further, unless otherwise noted, the use of the words “approximate,” “about,” “around,” “substantially,” etc., mean plus or minus ten percent.

The foregoing description of illustrative implementations has been presented for purposes of illustration and of description. It is not intended to be exhaustive or limiting with respect to the precise form disclosed, and modifications and variations are possible in light of the above teachings or may be acquired from practice of the disclosed implementations. It is intended that the scope of the invention be defined by the claims appended hereto and their equivalents.

What is claimed is:

1. A system, comprising:
a data processing system comprising memory and one or more processors to:
receive, via a user interface, an indication of a first series associated with one or more time stamps before a prediction time stamp indicating a start time of a prediction range;
segment a first time period associated with the first series into a second time period bounded by a first time stamp within the first time period and a second time stamp within the first time period and later than the first time stamp, and into a third time period bounded by a third time stamp within the first time period and later than the second timestamp and a fourth time stamp within the first time period and later than the third time stamp;
determine a first metric associated with the third time period and based on one or more first data points of a training data set associated with the first series and having time stamps bounded by the first time stamp and the second time stamp within the second time period;
generate one or more data points within the third time period based on the first metric;
generate, based on a model using machine learning and input comprising the data points generated within the third time period, one or more data points corresponding to a performance of a second series subsequent to the prediction time stamp;
present, via the user interface, a first presentation that indicates the performance of the second series subsequent to the prediction time stamp in a coordinate space including the third time period; and
present, via the user interface, a second presentation that indicates a region in the coordinate space including the third time period, the region corresponding to the performance of the second series subsequent to the prediction time stamp.

2. The system of claim 1, the data processing system further configured to:
detect, based on a number of data points having corresponding time stamps within the first time period, a characteristic indicating a distribution of data points of the first series.

3. The system of claim 2, the data processing system further configured to:
select, based on the characteristic indicating the distribution, a segmentation model operable to segment the first series; and
segment, in accordance with the selected segmentation model, the first time period.

4. The system of claim 3, the data processing system further configured to:
provide, via the user interface, a control affordance to receive input indicating the selection of the segmentation model.

5. The system of claim 2, the characteristic indicating presence of data points associated with the first series, absence of data points associated with the first series, or partial presence of data points associated with the first series.

6. The system of claim 1, the data processing system further configured to:
generate a first baseline metric associated with a third series of the model and based on one or more data points comprising training data of the third series; and
modify, based on the first baseline metric, values of one or more of the data points corresponding to the performance of the first series.

7. The system of claim 6, the first baseline metric corresponding to a mean value, a median value, a maximum value, a minimum value, an earliest value, or a latest value of the data points comprising training data of the third series.

8. The system of claim 6, the data processing system further configured to:
generate a second baseline metric associated with a fourth series of the model and based on one or more data points comprising training data of the fourth series; and
modify, based on a combination of the first baseline metric and the second baseline metric, values of one or more of the data points corresponding to the performance of the second series.

9. The system of claim 1, the data processing system further configured to:
generate, based on one or more second data points of a training data set associated with the first series and having time stamps between or matching the first time stamp and the second time stamp, a second metric associated with the second time period.

10. The system of claim 1, the first metric corresponding to a mean or median value of the first data points.

11. The system of claim 1, the region indicating a confidence interval corresponding to the performance.

12. A method, comprising:
receiving, via a user interface, an indication of a first series associated with one or more time stamps before a prediction time stamp indicating a start time of a prediction range;
segmenting a first time period associated with the first series into a second time period bounded by a first time stamp within the first time period and a second time stamp within the first time period and later than the first time stamp, and into a third time period bounded by a third time stamp within the first time period and later than the second timestamp and a fourth time stamp within the first time period and later than the third time stamp;
determining a first metric associated with the third time period and based on one or more first data points of a training data set associated with the first series and having time stamps bounded by the first time stamp and the second time stamp within the second time period;
generating one or more data points within the third time period based on the first metric;
generating, based on a model using machine learning and input comprising the data points generated within the third time period, one or more data points corresponding to a performance of a second series subsequent to the prediction time stamp;
presenting, via the user interface, a first presentation that indicates the performance of the second series subsequent to the prediction time stamp in a coordinate space including the third time period; and
presenting, via the user interface, a second presentation that indicates a region in the coordinate space including the third time period, the region corresponding to the performance of the second series subsequent to the prediction time stamp.

13. The method of claim 12, further comprising:
detecting, based on a number of data points having corresponding time stamps within the first time period, a characteristic indicating a distribution of data points of the first series according to presence of data points associated with the first series, absence of data points associated with the first series, or partial presence of data points associated with the first series.

14. The method of claim 13, further comprising:
selecting, based on the characteristic indicating the distribution, a segmentation model operable to segment the first series; and
segmenting, in accordance with the selected segmentation model, the first time period.

15. The method of claim 14, further comprising:
providing, via the user interface, a control affordance to receive input indicating the selection of the segmentation model; and
presenting, via the user interface and in a coordinate space including the third time period, the performance and a region indicating a confidence interval corresponding to the performance.

16. The method of claim 12, further comprising:
generating a first baseline metric associated with a third series of the model and based on one or more data points comprising training data of the third series; and
modifying, based on the first baseline metric, values of one or more of the data points corresponding to the performance of the first series,
the first metric corresponding to a mean or median value of the first data points, and the first baseline metric corresponding to a mean value, a median value, a maximum value, a minimum value, an earliest value, or a latest value of the data points comprising training data of the third series.

17. The method of claim 16, further comprising:
generating a second baseline metric associated with a fourth series of the model and based on one or more data points comprising training data of the fourth series; and
modifying, based on a combination of the first baseline metric and the second baseline metric, values of one or more of the data points corresponding to the performance of the second series.

18. The method of claim 12, further comprising:
generating, based on one or more second data points of a training data set associated with the first series and having time stamps between or matching the first time stamp and the second time stamp, a second metric associated with the second time period.

19. A computer readable medium including one or more instructions stored thereon and executable by a processor to:
receive, by the processor and via a user interface, an indication of a first series associated with one or more time stamps before a prediction time stamp indicating a start time of a prediction range;
segment, by the processor, a first time period associated with the first series into a second time period bounded by a first time stamp within the first time period and a second time stamp within the first time period and later than the first time stamp, and into a third time period bounded by a third time stamp within the first time period and later than the second timestamp and a fourth time stamp within the first time period and later than the third time stamp;
determine, by the processor, a first metric associated with the third time period and based on one or more first data points of a training data set associated with the first series and having time stamps bounded by the first time stamp and the second time stamp within the second time period;
generate, by the processor, one or more data points within the third time period based on the first metric;
generate, by the processor and based on a model using machine learning and input comprising the data points generated within the third time period, one or more data points corresponding to a performance of a second series subsequent to the prediction time stamp;
present, by the processor and via the user interface, a first presentation that indicates the performance of the second series subsequent to the prediction time stamp in a coordinate space including the third time period; and
present, by the processor and via the user interface, a second presentation that indicates a region in the coordinate space including the third time period, the region corresponding to the performance of the second series subsequent to the prediction time stamp.

20. The computer readable medium of claim 19, wherein the computer readable medium further includes one or more instructions executable by the processor to:
detect, by the processor and based on a number of data points having corresponding time stamps within the first time period, a characteristic indicating a distribution of data points of the first series;
provide, by the processor and via the user interface, a control affordance to receive input indicating the selection of the segmentation model;
select, by the processor and based on the characteristic indicating the distribution, a segmentation model operable to segment the first series; and
segment, by the processor and in accordance with the selected segmentation model, the first time period.
